(19) United States
(12) Patent Application Publication
(10) Pub. No.: US 2007/0176665 A1
(43) Pub. Date: Aug. 2, 2007

(54) Variable voltage attenuator circuits

(75) Inventors: Shuyun Zhang, Allston, MA (US); Rob McMorrow, Concord, MA (US)

Correspondence Address: WOLF GREENFIELD & SACKS, P.C., 600 ATLANTIC AVENUE, BOSTON, MA, 02210-2206, US

(73) Assignee: Analog Devices, Inc., Norwood, MA (US)

(21) Appl. No.: 11/345,579

(22) Filed: Feb. 1, 2006

(51) Int. Cl. H03L 5/00

(52) U.S. Cl. 327/308

(57) ABSTRACT

Methods and circuits are provided for controlling a signal applied to a control terminal of a variable voltage attenuator. In one embodiment, a method comprises detecting an output signal of the variable voltage attenuator, generating a logarithm of the detected output signal of the variable voltage attenuator, and generating the signal applied to the control terminal of the variable voltage attenuator at least partially based on the logarithm of the detected output signal of the variable voltage attenuator.

### BACKGROUND

Variable voltage attenuators (VVA) are standard components that can be utilized to adjust signal levels in radio frequency (RF) systems. VVAs are essentially transistor networks wherein the transistor channel resistance, and hence signal attenuation, may be controlled via the application of transistor gate (or base) voltages. For example, VVAs including gallium arsenide pseudomorphic high electron mobility transistors (PHEMT) are widely used in numerous RF applications due to their high signal linearity, wide dynamic range, low current consumption, and low insertion loss.

VVAs can provide a number of advantages over other signal attenuation techniques. For example, although active gain leveling loops can alternatively be used to attenuate signals, VVAs can alleviate problems associated with active gain leveling loops, such as signal distortion, high current consumption, and high added noise.

### SUMMARY

Various embodiments provide attenuation and power level control circuits, as well as related methods. Various embodiments can also allow for an extended linear-in-dB range.

In one embodiment, a method is provided for controlling a signal applied to a control terminal of a variable voltage attenuator. The method comprises detecting an output signal of the variable voltage attenuator, generating a logarithm of the detected output signal of the variable voltage attenuator, and generating the signal applied to the control terminal of the variable voltage attenuator at least partially based on the logarithm of the detected output signal of the variable voltage attenuator.

In one embodiment, a circuit includes a variable voltage attenuator comprising an input terminal, an output terminal, and a control terminal. The circuit comprises a first logarithmic signal detector having an input terminal coupled to the output terminal of the variable voltage attenuator, and a summing element having a first input terminal coupled to an output terminal of the first logarithmic signal detector and an output terminal coupled to the control terminal of the variable voltage attenuator.

In one embodiment, a circuit is provided which includes a variable voltage attenuator comprising an input terminal, an output terminal, and a control terminal. The circuit comprises means for detecting an output signal of the variable voltage attenuator, means for generating a logarithm of the detected output signal of the variable voltage attenuator, and means for generating the signal applied to the control terminal of the variable voltage attenuator at least partially based on the logarithm of the detected output signal of the variable voltage attenuator.

In one embodiment, a circuit comprises a first input terminal configured to receive an input signal, an output terminal configured to output an attenuated input signal, and a second input terminal configured to receive a set voltage that at least partially determines the attenuation of the attenuated input signal, wherein the attenuated input signal has a power such that the power versus the set voltage is linear-in-dB for a range of the set voltage greater than 0.5 V.

### BRIEF DESCRIPTION OF DRAWINGS

In the drawings, each identical or nearly identical component that is illustrated in various figures is represented by a like numeral. For purposes of clarity, not every component may be labeled in every drawing. In the drawings:

FIG. 1 is a schematic of a prior art VVA comprising a PI network of transistors;

FIG. 2 is a power plot for the prior art VVA of FIG. 1;

FIG. 3 is a schematic of an attenuation control circuit that can have an extended linear-in-dB range;

FIG. 4 is a functional schematic of one embodiment of the comparator in the circuit of FIG. 3;

FIG. 5 is a schematic of an attenuation control circuit that can have an extended linear-in-dB range and having a digital interface;

FIG. 6 is a schematic of a power level control circuit that can have an extended linear-in-dB range;

FIG. 7 is a schematic of a power level control circuit that can have an extended linear-in-dB range and having a digital interface;

FIG. 8 is plot of measured output power versus control voltage applied to a VVA control terminal of the power level control circuit of FIG. 6;

FIG. 9 is plot of linear-in-dB error of the measured output power versus set voltage of the power level control circuit of FIG. 6;

FIG. 10 is a connection schematic of a multi-chip module that can comprise any one of the circuits illustrated in FIGS. 3-5; and

FIG. 11 is a connection schematic of a multi-chip module that can comprise any one of the circuits illustrated in FIGS. 6-7.

### DETAILED DESCRIPTION

As previously mentioned, existing VVAs are composed of transistor networks (e.g., PI, T networks) that rely on the variable channel resistance of transistors to attenuate a signal. Networks of transistors are typically utilized as opposed to a single transistor, since networks can be configured to enable the control of the input and output impedance of the VVA. For example, PI and T networks are commonly used to allow for such impedance matching.

Although simple in principle, existing VVAs can have numerous drawbacks. One problem is the lack of a simple relationship between the attenuation and the control voltage, which in many cases may be non-linearly related. Furthermore, the slope of the attenuation versus the control voltage can be significantly large, thereby making precise control of the attenuation via modulation of the control voltage difficult. The attenuation may also depend on both frequency and temperature, in addition to depending on the control voltage, thereby resulting in the unpredictability of the attenuation for a given fixed control voltage. Multiple control signals may often be used to properly control the various transistors in the network, and more specifically, complimentary control signals may sometimes be employed. The circuits used to generate these complementary control signals may be quite complex so as to properly account for the aforementioned limitations.

The aforementioned problems result in VVAs that are difficult to successfully implement in practice. For example, such VVAs may require considerable calibration and the use of temperature sensors to compensate for temperature variation effects. To further exacerbate these limitations, most circuit applications that require high performance VVAs (e.g., PHEMT VVAs) may also have demanding accuracy specifications, which may be difficult to satisfy using existing VVAs.

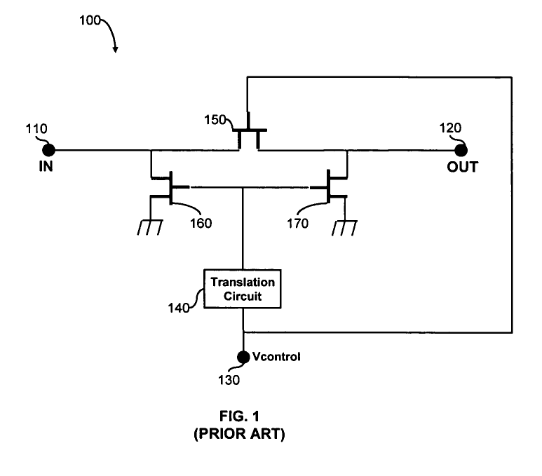

For the purposes of illustrating some of the aforementioned drawbacks of existing VVAs, FIG. 1 shows a prior art VVA 100 comprising a PI network including transistors 150, 160, and 170, and a translation circuit 140. The translation circuit 140 may comprise circuits that can generate a complimentary control signal as is known to those of skill in the art. The prior art VVA 100 also includes input terminal 110, output terminal 120, and control terminal 130.

During operation of the prior art VVA 100, an input signal applied to input terminal 110 may be attenuated as a result of the channel resistances of transistors 150, 160, and 170. As a result, an output signal on output terminal 120 is an attenuated version of the input signal on input terminal 110.

To control the channel resistances (e.g., source to drain resistance) of transistors 150, 160, and 170, signals applied to the control terminals (e.g., gates or bases) of the transistors 150, 160, and 170 may be controlled via the application of a control signal (e.g., a control voltage referred to as V_{control}) applied to control terminal 130. The control signal applied to control terminal 130 can be directly applied to the control terminal of transistor 150 so as to determine the channel resistance of transistor 150.

Furthermore, the translation circuit 140 can generate a complimentary signal that may be applied to the control terminals of transistors 160 and 170 and hence may in turn set the channel resistances of transistors 160 and 170. The translation circuit 140 may be such that the generated complimentary signal can vary inversely with the control signal applied to control terminal 130; specifically, the complimentary signal generated by the translation circuit 140 decreases as the control signal increases, and vice versa. The application of such a complimentary signal on the control terminals of transistors 160 and 170 can ensure appropriate attenuation and proper impedance matching.

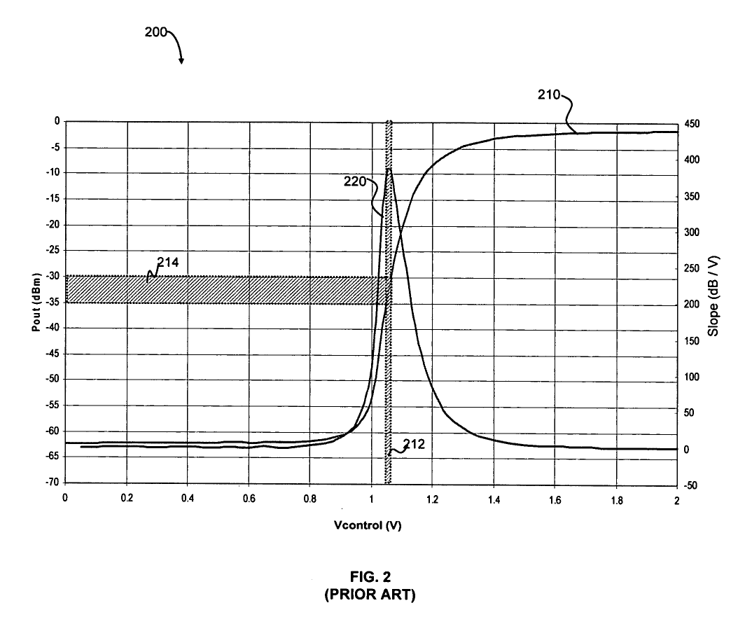

FIG. 2 illustrates a typical output power plot 200 for the prior art VVA 100. In this example, the VVA is formed with PHEMT transistors and has an applied input signal having a frequency of 900 MHz and an input power Pᵢₙ of 0 dBm. Plot 200 includes a vertical axis associated with the power of the output signal generated by the VVA, where the output power Pₒᵤₜ is given in dBm. The horizontal axis of plot 200 is associated with control voltage V_{control} applied to the control terminal of the prior art VVA. Curve 210 illustrates the relationship between the output power versus the control voltage, indicating that the power outputted by the VVA is a function of the control voltage applied to the control terminal of the VVA. Curve 220 illustrates the dependence of the slope of curve 210 on the control signal, thereby showing the lack of significant “linearity-in-dB”.

A dependant quantity (e.g., power ratios, voltage ratios, etc.) is “linear-in-dB” with respect to an independent variable when the dependant quantity represented in dB (i.e., logarithmically via 10log₁₀(quantity)) varies linearly with the independent variable. Since the dependant quantity may only be linear-in-dB for a limited range of the independent variable, a linear-in-dB independent variable range is defined as a range of the independent variable for which the dependent variable in dB varies linearly with the independent variable. Similarly, a linear-in-dB dependant quantity range is defined as a range of the quantity for which the dependent quantity in dB varies linearly with the independent variable.

A linear-in-dB range can be used to characterize a suitable operation range of a VVA. For example, in the case of a VVA, such as VVA 100, the dependant quantity can be power attenuation (i.e., the ratio of output to input power, Pₒᵤₜ/Pᵢₙ) and the independent variable can be the control voltage applied to the control terminal of the VVA. In this example, the linear-in-dB control voltage range is the control voltage range for which the power attenuation in dB varies linearly with the control voltage. Furthermore, the linear-in-dB attenuation range is the range of the attenuation for which the attenuation in dB varies linearly the control voltage.

Alternatively or additionally, the dependant quantity need not be power attenuation but rather may be the output power for a given fixed input power. In such a case, a similar characterization can also be applied, but in such instances, the dependant quantity is the output power Pₒᵤₜ represented in dBm (i.e., decibels relative to one milliWatt and given by 10log₁₀(power in milliWatts)) and the independent variable can be the control voltage applied to the control terminal. In such instances, the output power is linear-in-dB with respect to the control voltage when the output power in dBm varies linearly with respect to the control voltage.

In the example of FIG. 2, a linear-in-dB range of the prior art VVA 100 is depicted by ranges 212 and 214. Specifically, range 212 is a control voltage range for which the output power in dBm is substaintially linear with respect to the control voltage. Range 214 is the corresponding output power range for which the output power in dBm is substaintially linear with respect to the control voltage. As should be appreciated from this illustration, the prior art VVA has a limited linear-in-dB range. Specifically, the output power is substantially linear-in-dB over a small range of control voltages of about 80 milivolts (mV). The corresponding range of output powers for which linearity-in-dB holds is about 5 dBm. As such, the dynamic range of this prior art VVA would be substantially limited. Furthermore, the large slope (given by curve 220) of about 380 dBm/V makes the precise control of the output power difficult.

Applicants have appreciated that the limited linear-in-dB range of the output power (or power attenuation) versus the control voltage for some prior art VVAs can result in difficulties using such prior art VVAs in feedback control loops and other circuit applications. Applicants have also appreciated that extending the linear-in-dB range of a VVA may facilitate the use of VVAs in a variety of circuit applications. The extension of the linear-in-dB range can be a result of utilizing the output signal of the VVA to at least partially control the attenuation level of the VVA, by establishing a feedback from the output of the VVA to the control terminal of the VVA.

In accordance with one embodiment, a method is provided for controlling a signal applied to a control terminal of a variable voltage attenuator. The method includes acts of detecting an output signal of the variable voltage attenuator, and generating the signal applied to the control terminal of the variable voltage attenuator at least partially in response to the detected output signal of the variable voltage attenuator. In accordance with some embodiments, as a result of generating the signal applied to the control terminal of the variable voltage attenuator at least partially in response to the detected output signal of the variable voltage attenuator, a linear-in-dB range of the output signal versus a set signal is extended as compared to a linear-in-dB range of the variable voltage attenuator alone.

In another embodiment, an attenuation control circuit is provided that includes a variable voltage attenuator, where the variable voltage attenuator includes an input terminal, an output terminal, and a control terminal, and the circuit includes a coupling of the output terminal of the variable voltage attenuator to the control terminal of the variable voltage attenuator. In accordance with some embodiments, the attenuation control circuit may be configured to have an extended linear-in-dB range for the attenuation (or output power) versus a set signal, as compared to the linear-in-dB range of the variable voltage attenuator alone.

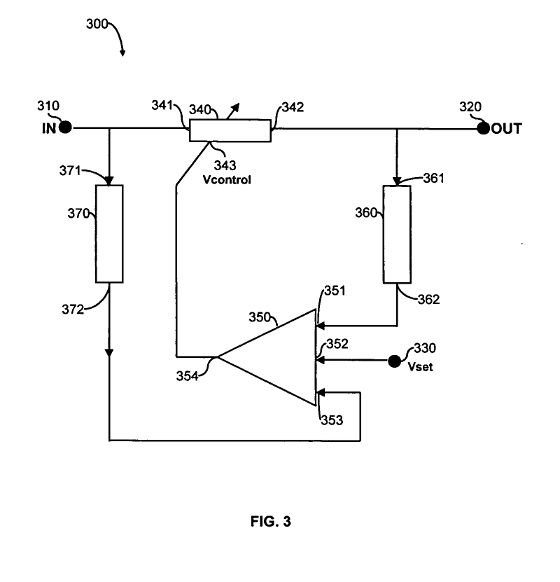

FIG. 3 illustrates an attenuation control circuit 300 that can have an extended linear-in-dB range, in accordance with some embodiments of the invention. The circuit 300 includes a VVA 340, which can be any type of VVA. For example, the VVA 340 may be the VVA 100 illustrated in FIG. 1. Alternatively, the VVA 340 may comprise of a T network of transistors or any other network or transistors. The VVA 340 may be formed using transistors of any type, and using any materials and associated process technologies. The VVA 340 includes an input terminal 341, an output terminal 342, and a control terminal 343. A control signal having a control voltage V_{control} can be applied to the control terminal 343 and can determine the attenuation level of the VVA 340.

The attenuation control circuit 300 includes an input terminal 310, an output terminal 320, and a set terminal 330. The input terminal 310 can be configured to receive an input signal, and an output signal may be outputted on the output terminal 320. The signal applied to input terminal 310 can be any signal for which attenuation is desired, as the invention is not limited in this respect. For example, input terminal 310 can receive an applied RF signal, which, upon attenuation, may be outputted on output terminal 320 and then fed into one or more components of an RF system, such as a transceiver.

Furthermore, the set terminal 330 can be configured to receive an applied analog set signal having a set voltage Vₛₑₜ which can control the attenuation level of the attenuation control circuit 300, where the attenuation is defined as the ratio of the output signal power (on terminal 320) over the input signal power (on terminal 310).

The attenuation control circuit 300 is such that the input terminal 310 can be coupled to the input terminal 341 of the VVA 340, and the output terminal 342 of the VVA 340 may be coupled to the output terminal 320 of the attenuation control circuit 300. The output terminal 320 may also be coupled to an input terminal 361 of an output signal detector 360. The output signal detector 360 may comprise a power detector (e.g., a logarithmic amplifier power detector), a voltage detector, or any other type of signal detector, as the invention is not limited in this respect. The output signal detector 360 can output a signal, on output terminal 362, which may be functionally related to the signal outputted by the VVA 340.

In embodiments where the output signal detector 360 is a logarithmic amplifier power detector, the signal on output terminal 362 has a voltage proportional to the logarithm of the power of the output signal on output terminal 320. Furthermore, the proportionality constant associated with the logarithmic transfer function of the logarithmic amplifier power detector may be determined by a configuration voltage applied to the logarithmic amplifier power detector (not shown in diagram).

The attenuation control circuit 300 may also include an input signal detector 370 having an input terminal 371 and an output terminal 372. The input signal detector 370 may comprise a power detector (e.g., a logarithmic amplifier power detector), a voltage detector, or any other type of signal detector, as the invention is not limited so. The input signal detector 370 can output a signal, on an output terminal 372, which may be functionally related to the input signal on input terminal 310 of the attenuation control circuit 300.

In embodiments where the input signal detector 370 is a logarithmic amplifier power detector, the signal on output terminal 372 has a voltage proportional to the logarithm of the power of the input signal on input terminal 310. Moreover, the proportionality constant associated with the logarithmic transfer function of the logarithmic amplifier power detector may be determined by a configuration voltage applied to the logarithmic amplifier power detector (not shown in diagram).

The attenuation control circuit 300 may also include a comparator 350 having input terminals 351, 352, and 353, and an output terminal 354. The input terminal 351 may be coupled to the output terminal 362 of the output signal detector 360, the input terminal 353 may be coupled to the output terminal 372 of the input signal detector 370, and the input terminal 352 may be coupled to the set terminal 330. The output terminal 354 of the comparator 350 may be coupled to the control terminal 343 of the VVA 340.

The comparator 350 can combine signals on input terminals 351, 352, and 353, and output a signal derived from the combined signals on the output terminal 354. It should be appreciated that one or more of the input signals on the comparator input terminals 351, 352, and 353 can be negated, within the comparator 350, prior to the summation of the signals. In one embodiment, the input signal on input terminal 351 is negated prior to summing within the comparator, whereas the signals on the input terminals 352 and 353 are not negated. The aforementioned signals are summed within the comparator and the result of the summation may be amplified so as to generate an output signal on output terminal 354. In one embodiment, the gain of the comparator 350 can be substantially large so as to act as an infinite gain, or, in other embodiments, the gain may have any desired value, as the invention is not limited in this respect.

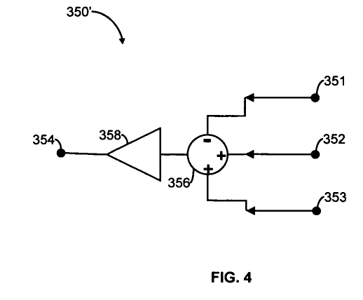

FIG. 4 illustrates a functional schematic 350′ of one embodiment of the comparator 350 shown in FIG. 3. The functional schematic 350′ of the comparator includes a summing element 356 that combines a negated signal of the signal applied to terminal 351 with signals applied to terminals 352 and 353. The summing element 356 outputs the combined signal which can be fed into an input terminal of amplifier 358. The output of amplifier 358 may be coupled to output terminal 354 corresponding to the output terminal of comparator 350 (FIG. 3). The amplifier 358 can have a gain that is substantially large so as to act as an infinite gain, or may have any other gain value, as the invention is not limited in this respect.

In some embodiments, the components of the attenuation control circuit 300 may include one or more types of transistors including PHEMTs, metal-oxide-semiconductor field-effect transistors (MOSFETs), metal-semiconductor field-effect transistors (MESFETs), bipolar junction transistors (BJTs), heterojunction bipolar transistors (HBTs), and/or any other type of transistor, as the invention is not limited so. In one embodiment, the VVA 340 may be a PHEMT VVA (e.g., a GaAs PHEMT VVA) and the remaining components, namely the input signal detector 370, the output signal detector 360, and the comparator 350 can be silicon integrated circuits (e.g., including silicon MOSFETs and/or BJTs). It should be appreciated that the above example is merely one example, and other device technologies may be utilized to achieve desired performance levels according to specification parameters for given applications. For example, the attenuation control circuit may be used to attenuate signals having a carrier frequency greater than about 30 MHz, greater than about 900 MHz, greater than about 1.5 GHz, greater than about 10 GHz, or greater than 20 GHz.

During the operation of the attenuation control circuit 300, the output signal detector 360 samples the output signal on output terminal 320 and the input signal detector 370 samples the input signal on input terminal 310. The signal detectors 360 and 370 generate signals that are combined, in comparator 350, along with the set signal (Vₛₑₜ) applied to set terminal 330. The combined signal can be amplified within the comparator 350 and fed into the control terminal 343 of the VVA 340 so as to control the attenuation level. In doing so, via a feedback loop that couples the output signal on output terminal 320 to the control terminal of the VVA 343, the linearity of circuit 300 can be extended, as compared to the linearity of the VVA alone.

In some embodiments, the signal detectors 360 and 370 are logarithmic amplifier power detectors and the comparator 350 negates the signal applied to terminal 351. In such embodiments, the combined signals of terminals 351, 352, and 353 form a combined signal given by Δ=Vₛₑₜ+K log(Pᵢₙ)−Klog(Pₒᵤₜ)=Vₛₑₜ−K log(Pₒᵤₜ/Pᵢₙ), where Pᵢₙ is the input power on terminal 310, Pₒᵤₜ is the output power on terminal 320, Vₛₑₜ is the voltage of the set signal applied to set terminal 330, and K is a proportionality constant that depends on the signal detector configuration settings. This combined signal A can be generated and amplified within the comparator 350 so as to generate an output signal AΔ+V_{offset}, where A is the gain of the comparator 350 and an offset voltage may be added to the signal. The output signal is then fed to the control terminal 343 of the VVA 340. In so doing, the combined signal, given by AVₛₑₜ−AK log(Pₒᵤₜ/Pᵢₙ)+V_{offset}, serves as a control signal that determines the attenuation of the VVA 340.

It should be appreciated that since the combined signal depends on the input and output power, Pᵢₙ and Pₒᵤₜ, the control signal applied to the control terminal 343 of the VVA 340 depends recursively on the attenuation of circuit 300 (i.e., a feedback path is established). Although such a feedback circuit may not be amendable to the determination of an analytical function for attenuation versus analog set voltage Vₛₑₜ, the qualitative effect of the feedback coupling may be understood to be such that in steady state, the combined signal Δ approaches zero and therefore log(Pₒᵤₜ/Pᵢₙ) is substantially proportional to Vₛₑₜ. Therefore, as a result of the feedback system, the linear-in-dB range of the circuit 300 may be extended as compared to the VVA 340 alone.

In some embodiments, the linear-in-dB range of the attenuation control circuit 300 may be limited by the operation range of signal detectors 360 and 370. In some embodiments, the signal detectors 360 and 370 may have maximum operation frequency greater than or equal to about the input signal frequency. In some embodiments, circuit 300 may have an associated loop bandwidth that is greater than the maximum frequency of the input signal applied to input terminal 310.

Embodiments of circuit 300 that include logarithmic amplifier power detectors 360 and 370 may have an attenuation that is substantially linear-in-dB for an extended range of the set voltage Vₛₑₜ and substantially stable with variations in temperature and/or frequency. As such, circuit 300 can retain the performance advantages associated with a high performance VVA (e.g., a PHEMT VVA), while extending the linear-in-dB range of the VVA. In some embodiments, the circuit 300 can be implemented as a single package solution which can include a high performance VVA and associated control circuitry, so as to result in a compact, high performance attenuation circuit with an extended linear-in-dB range.

In some embodiments, a digital interface, which can include a digital-to-analog converter, may be provided to an attenuation control circuit so as to enable the input of a digital set signal to control the attenuation level of the attenuation control circuit.

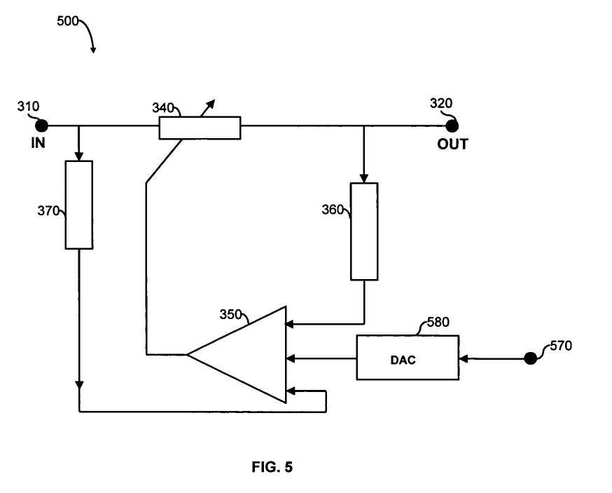

FIG. 5 illustrates such an embodiment wherein an attenuation control circuit 500 includes components of the attenuation control circuit 300 and a digital-to-analog converter 580. In this illustration, a set terminal 570 can receive an applied digital set signal which may be coupled to the input of the digital-to-analog converter 580. The digital-to-analog converter 580 can in turn generate an analog set signal having a set voltage Vₛₑₜ based on the inputted digital set signal. The analog set signal is outputted by the digital-to-analog converter and coupled into comparator 350. The other components of circuit 500 correspond to like-numbered components of circuit 300, and have been previously described. Furthermore, the operation of attenuation control circuit 500 is similar in other respects to the previously described operation of circuit 300. The only difference being that a digital set signal applied to set terminal 570 is converted to an associated analog set signal having a set voltage Vₛₑₜ prior to input into the comparator 350.

In another embodiment, a power level control circuit is provided that includes a variable voltage attenuator, where the variable voltage attenuator includes an input terminal, an output terminal, and a control terminal, and the circuit includes a coupling of the output terminal of the variable voltage attenuator to the control terminal of the variable voltage attenuator. In accordance with some embodiments, the power level control circuit may be configured to have an extended linear-in-dB range for the output power versus a set signal, as compared to the linear-in-dB range of the variable voltage attenuator alone.

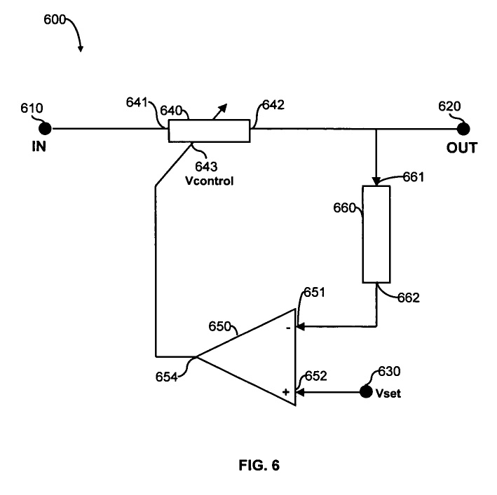

FIG. 6 illustrates a power level control circuit 600 that can have an extended linear-in-dB range, in accordance with some embodiments of the invention. The circuit 600 includes a VVA 640, which can be any type of VVA. For example, the VVA 640 may be the VVA 100 illustrated in FIG. 1. Alternatively, the VVA 640 may comprise of a T network of transistors or any other network or transistors. The VVA 640 may be formed using transistors of any type, and using any materials and associated process technologies. The VVA 640 includes an input terminal 641, an output terminal 642, and a control terminal 643. A control signal having a control voltage V_{control} can be applied to the control terminal 643 and can determine the attenuation level of the VVA 640.

The attenuation control circuit 600 includes an input terminal 610, an output terminal 620, and a set terminal 630. The input terminal 610 can be configured to receive an input signal, and an output signal may be outputted on the output terminal 620. The signal applied to input terminal 610 can be any signal for which attenuation is desired, as the invention is not limited in this respect. For example, input terminal 610 can receive an applied RF signal, which, upon attenuation, may be outputted on output terminal 620 and then fed into one or more components of an RF system, such as a transceiver.

Furthermore, the set terminal 630 can be configured to receive an applied analog set signal having a set voltage Vₛₑₜ which can control the output power level (on terminal 620) of the power level control circuit 600.

The power level control circuit 600 is such that the input terminal 610 can be coupled to the input terminal 641 of the VVA 640, and the output terminal 642 of the VVA 640 may be coupled to the output terminal 620 of the power level control circuit 600. The output terminal 620 may also be coupled to an input terminal 661 of an output signal detector 660. The output signal detector 660 may comprise a power detector (e.g., a logarithmic amplifier power detector), a voltage detector, or any other type of signal detector, as the invention is not limited in this respect. The output signal detector 660 can output a signal, on output terminal 662, which may be functionally related to the signal outputted by the VVA 640.

In embodiments where the output signal detector 660 is a logarithmic amplifier power detector, the signal on output terminal 662 has a voltage proportional to the logarithm of the power of the output signal on output terminal 620. Furthermore, the proportionality constant associated with the logarithmic transfer function of the logarithmic amplifier power detector may be determined by a configuration voltage applied to the logarithmic amplifier power detector (not shown in diagram).

The power level control circuit 600 may also include a comparator 650 having input terminals 651, and 652, and an output terminal 654. The input terminal 651 may be coupled to the output terminal 662 of the output signal detector 660, and the input terminal 652 may be coupled to the set terminal 630. The output terminal 654 of the comparator 650 may be coupled to the control terminal 643 of the VVA 640.

The comparator 650 can combine the signals on input terminals 651 and 652, and output a signal derived from the combined signals on the output terminal 654. It should be appreciated that one or more of the input signals on the comparator input terminals 651 and 652 can be negated, within the comparator 650, prior to the summation of the signals. In one embodiment, the input signal on input terminal 651 is negated prior to summing within the comparator, whereas the signal on the input terminal 352 is not negated. The aforementioned signals are summed within the comparator and the result of the summation is amplified so as to generate an output signal on output terminal 654. In one embodiment, the gain of the comparator 650 can be substantially large so as to act as an infinite gain, or, in other embodiments, the gain may have any desired value, as the invention is not limited in this respect.

In some embodiments, the components of the power level control circuit 300 may include one or more types of transistors including PHEMTs, MOSFETs, MESFETs, BJTs, HBTs, and/or any other type of transistor, as the invention is not limited so. In one embodiment, the VVA 640 may be a PHEMT VVA (e.g., a GaAs PHEMT VVA) and the remaining components, namely the output signal detector 660, and the comparator 650 can be silicon integrated circuits (e.g., including silicon MOSFETs and/or BJTs). It should be appreciated that the above example is merely one example, and other device technologies may be utilized to achieve desired performance levels according to specification parameters for given applications. For example, the power level control circuit may be used to set the output power of a signal having a carrier frequency greater than about 30 MHz, greater than about 900 MHz, greater than about 1.5 GHz, greater than about 10 GHz, or greater than 20 GHz.

During the operation of the power level control circuit 600, the output signal detector 660 samples the output signal on output terminal 620. The signal detector 660 generates a signal that is combined, in comparator 650, with the set signal (Vₛₑₜ) applied to set terminal 630. The combined signal can be amplified within the comparator 650 and fed into the control terminal 643 of the VVA 640 so as to control the attenuation level of the VVA 640. In doing so, via a feedback loop that couples the output signal on output terminal 620 to the control terminal of the VVA 643, the linearity of circuit 600 can be extended, as compared to the linearity of the VVA alone.

In some embodiments, the signal detector 660 is a logarithmic amplifier power detector and the comparator 650 negates the signal applied to terminal 651. In such embodiments, the combined signals on terminals 651 and 652 form a combined signal given by Δ=Vₛₑₜ−Klog(Pₒᵤₜ), where Pₒᵤₜ is the output power on terminal 620, Vₛₑₜ is the voltage of the set signal applied to set terminal 630, and K is a proportionality constant that depends on the signal detector configuration settings. This combined signal A can be generated and amplified within the comparator 650 so as to generate an output signal AΔ+V_{offset}, where A is the gain of the comparator 650 and an offset voltage may be added to the signal. The output signal is then fed to the control terminal 643 of the VVA 640. In so doing, the combined signal, given by AVₛₑₜ−AK log(Pₒᵤₜ)+V_{offset}, serves as a control signal that determines the attenuation of the VVA 640.

It should be appreciated that since the combined signal depends on the output power Pₒᵤₜ, the control signal applied to the control terminal 643 of the VVA 640 depends recursively on the attenuation of circuit 600 (i.e., a feedback path is established). Although such a feedback circuit may not be amendable to the determination of an analytical function for output power level versus analog set voltage Vₛₑₜ, the qualitative effect of the feedback coupling may be understood to be such that in steady state, the combined signal Δ approaches zero and therefore log(Pₒᵤₜ) is substantially proportional to Vₛₑₜ. Therefore, as a result of the feedback system, the linear-in-dB range of the circuit 600 may be extended as compared to the VVA 640 alone.

In some embodiments, the linear-in-dB range of the attenuation control circuit 600 may be limited by the operation range of signal detector 660. In some embodiments, the signal detector 660 may have maximum operation frequency greater than or equal to about the input signal frequency. In some embodiments, circuit 600 may have an associated loop bandwidth that is greater than the maximum frequency of the input signal applied to input terminal 610.

Embodiments of circuit 600 that include logarithmic amplifier power detector 660 may have an output power that is substantially linear-in-dB for an extended range of the set voltage Vₛₑₜ and substantially stable with variations in temperature and/or frequency. In some embodiments, the circuit 600 can be implemented as a single package solution which can include a high performance VVA and associated control circuitry, so as to result in a compact, high performance power level control circuit with an extended linear-in-dB range.

In some embodiments, a digital interface, which can include a digital-to-analog converter, may be provided to a power level control circuit so as to enable the input of a digital set signal to control the output power level of the power level control circuit.

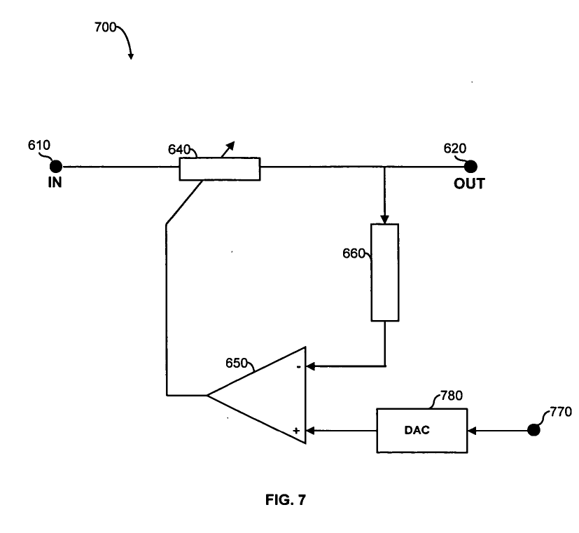

FIG. 7 illustrates such an embodiment wherein a power level control circuit 700 includes components of the power level control circuit 600 and a digital-to-analog converter 780. In this illustration, a set terminal 770 can receive an applied digital set signal which may be coupled to the input of the digital-to-analog converter 780. The digital-to-analog converter 780 can in turn generate an analog set signal having a set voltage Vₛₑₜ based on the inputted digital set signal. The analog set signal is outputted by the digital-to-analog converter and coupled into comparator 650. The other components of circuit 700 correspond to like-numbered components of circuit 600, and have been previously described. Furthermore, the operation of attenuation control circuit 700 is similar in other respects to the previously described operation of circuit 600. The only difference being that a digital set signal applied to set terminal 770 is converted to an associated analog set signal having a set voltage Vₛₑₜ prior to input into the comparator 650.

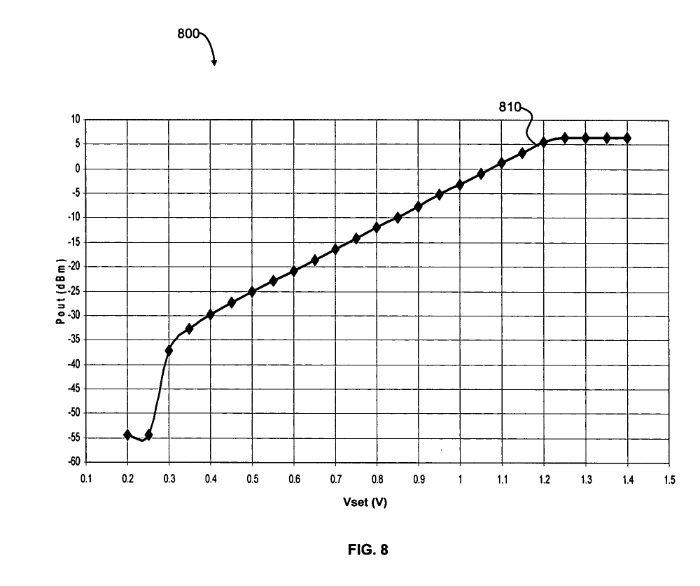

FIG. 8 illustrates a plot 800 of measured output power versus set voltage Vₛₑₜ of a power level control circuit, such as circuit 600 illustrated in FIG. 6. For these measurements, the VVA was a GaAs PHEMT VVA similar to the VVA 100 illustrated in FIG. 1. The output signal detector (which was a logarithmic detector in this embodiment) and the comparator functionality was provided by Analog part AD8315 offered by Analog Devices of Norwood, Massachusetts. Furthermore, the applied input signal had a frequency of 900 MHz and an input power Pᵢₙ of 10 dBm.

The plot 800 includes a curve 810 showing the functional relationship between the output power in dBm versus the set voltage Vₛₑₜ. As can be seen from the plot 800, the linear-in-dB range is significantly extended as compared to the range of the VVA with no feedback (FIG. 2). Specifically, for this illustrative measurement, the output power is linear-in-dB for set voltages between about 0.4 V to about 1.1 V, giving a voltage range of about 0.7 V. In some embodiments, the output power is linear-in-dB for set voltages between about 0 V to about 2.0 V. In further embodiments, the linear-in-dB range can be designed to have any desirable range via scaling and shifting of the inputted set voltage using a linear DC amplifier and a voltage divider, respectively. In some embodiments, the range of set voltages for which the output power (or attenuation) is linear-in-dB is greater than about 0.5 V, greater than about 1.0 V, or greater than about 2.0 V.

Also, in this illustrative measurement, the dynamic range for which the output power is linear-in-dB with respect to the VVA control voltage is about 40 dBm, which is significantly larger dynamic range as compared to the VVA alone with no feedback (FIG. 2). The linear-in-dB range may be limited by the signal detector (e.g., detector 360), namely the range of the logarithmic amplifier utilized in the power level control circuit. In some embodiments, the dynamic range is greater than about 10 dB, greater than about 20 dB, greater than about 60 dB, or greater than 90 dB.

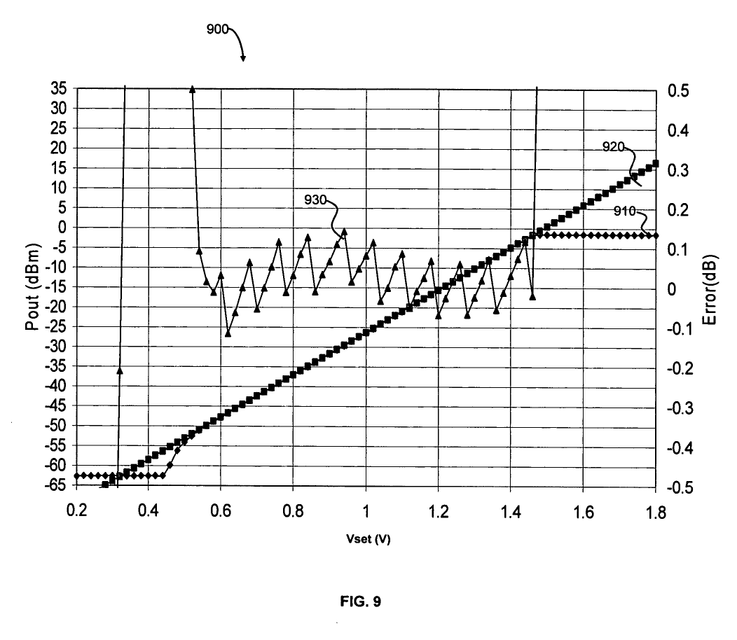

FIG. 9 illustrates a plot 900 of a linear-in-dB error (in dB) curve 930 defined as the difference between an ideal linear-in-dB curve 920 and a measured output power curve 910. The curve 910 is the measured output power versus the set voltage applied to the set terminal of the power level control circuit, such as circuit 600 described in FIG. 6. The circuit components and parameters were similar to those used for the measurement shown in FIG. 8 (e.g., part AD8315), except that the GaAs PHEMT VVA used had a higher dynamic range and the applied input signal had an input power Pᵢₙ of about 0 dBm.

Curve 920 shows an ideal linear-in-dB fit to the curve 910, and the linear-in-dB error curve 930 shows the difference between the ideal linear-in-dB curve 920 and the measured output power curve 910. As can be seen from curve 930, the linear-in-dB error is less than about ±0.2 dB for a set voltage between about 0.6 V and about 1.4 V. Is should be appreciated that the linear-in-dB error for a specific voltage range depends on the performance of the component parts and the operating parameters. In the illustration of FIG. 9, the linear-in-dB error of less than about ±0.2 dB for set voltage between about 0.6 V and about 1.4 V is specific to the use of part AD8315, but the invention is not limited in this respect. Also, as described above, the set voltage range for which the output is linear-in-dB can be scaled and shifted, and therefore can have any desirable range. In some embodiments, the linear-in-dB error may be less than about ±0.2 dB for a set voltage range of greater than about 0.5 V (e.g., greater than 1.0 V, greater than 1.5 V, greater than 2.0 V, greater than 3.0 V).

In some embodiments, attenuation control circuits and/or the power level control circuits including a VVA possess a dynamic range of greater than or equal to about 50 dB with high accuracy. In some embodiments, the conformance to linear-in-dB control (i.e., linear-in-dB error) is less than or equal to about ±0.2 dB (as compared to several dB for some prior art solutions and stand-alone VVAs). In some embodiments, the stability over temperature is less than or equal to about ±0.5 dB (as compared to several dB for prior art solutions). In some embodiments the stability over frequency is less than about ±0.5 dB (versus more than about 5 dB for some prior art solutions and stand-alone VVAs).

In the embodiments described above, it should be understood that any VVA may be used in the circuits, irrespective of the type of the VVA, the VVA linear-in-dB range, and/or any other attribute of the VVA, as the invention is not limited in this respect. For example, the VVAs used in the circuits may comprise PI networks, T networks, or any other type of circuit network. Furthermore, one or more types of transistors may be used to construct the VVAs. For example, the transistors may include PHEMTs, MOSFETs, MESFETs, BJTs, HBTs, and/or any other type of transistor, as the invention is not limited in this respect. The transistors may be formed of any suitable material, including semiconductors such as silicon, silicon germanium, gallium arsenide, gallium nitride, and/or any other type of suitable semiconductor, as the invention is not limited in this respect either.

It should also be appreciated that circuit components used for controlling the VVA need not be formed using the same device technology as the VVA. For example, in some embodiments, the VVA can include PHEMTs (e.g., gallium arsenide PHEMTs) and some or all of the controlling circuitry can include MOSFETs (e.g., Si MOSFETs), BJTs (e.g., Si BJTs), and/or HBT (e.g., SiGe HBTs). Moreover, the controlling circuitry may be integrated into a single die or may be included in a packaged assembly of multiple dies. In addition, the VVA may be packaged with the associated control circuitry in a single package assembly. When both the VVA and some or all of the controlling components are formed using the same process technology, the VVA and the aforementioned controlling components may be integrated onto a single die, but the invention is not limited so.

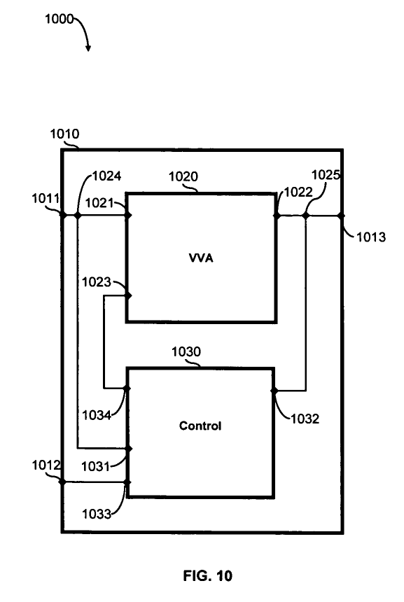

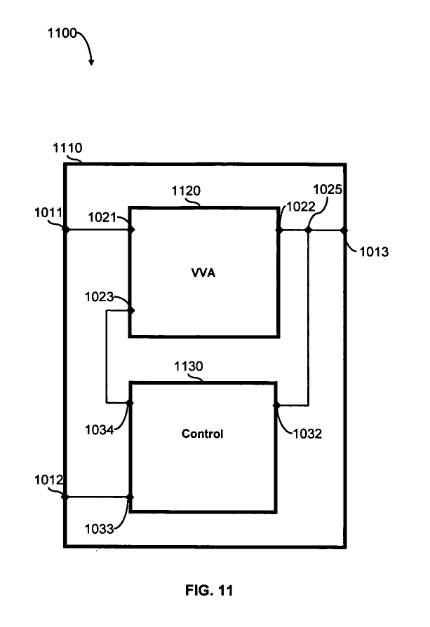

FIG. 10 and 11 are connection schematics for embodiments where multi-chip modules include any one of the circuits illustrated in FIGS. 3-7, or any other circuits implementing VVA control methods. A multi-chip module may facilitate the combination of various device technologies into a single package. Although the circuits and methods presented herein may be implemented using a single device technology, the use of multiple technologies may enable the tailoring of device technology to various functions in the circuit. For example, VVAs formed with GaAs PHEMTs may have desirable performance characteristics (e.g., low noise figures, linearity, etc.) as compared to MOSFET technologies, whereas the control circuit components that control the VVA may be formed using MOSFET technologies (e.g., Si MOSFETs). Such an approach can combine the benefits of a various technologies, for example high performance and/or low cost, as desired for the various components that form the circuit.

FIG. 10 is a connection schematic 1000 for a multi-chip module 1010 comprising any one of the circuits illustrated in FIGS. 3-5, or circuits having similar functionality. Multi-chip module 1010 includes a VVA chip die 1020 and a control die 1030, although other chip dies may also be incorporated in the multi-chip module to perform other functions, as the invention is not limited in this respect. The VVA chip die 1020 and the control chip die 1030 are connected via various connections (not labeled), which enable both output and input signals to be communicated between the dies.

Connection terminals are present between the internal dies 1020 and 1030 and the external terminals of the multi-chip module 1010. Connection terminals allow for the input of an input signal via external input terminal 1011 and the input of a set signal (Vₛₑₜ) that sets the desired attenuation level via external set terminal 1012. An attenuated input signal can be outputted via external output terminal 1013.

The external multi-chip module terminals may be connected to input and output terminals on the internal dies 1020 and 1030. In the illustration of FIG. 10, external input terminal 1011 is connected to input terminal 1021 of the VVA die 1020 and to input terminal 1031 of the control die 1030 (via connection 1024). These connections allow the input signal to be inputted to both the VVA die 1020 and the control die 1030. Similarly, the output terminal 1022 of the VVA die 1020 may be connected to the external output terminal 1013 of the multi-chip module 1010, and also connected to terminal 1032 of the control die 1030 (via connection 1025). Such a connection enables the attenuated signal generated by the VVA die 1020 to be outputted to external output terminal 1013 and also to be fed into the control die 1030 via terminal 1032, thereby enabling an output feedback control loop to be established, as previously described. Also, an output control terminal 1034 on the control die 1030 may be connected to an input control terminal 1023 on the VVA die 1020. Such a connection allows the control signal generated by the control die 1030 to be transmitted to the VVA die 1020, and thereby control the attenuation level of the VVA. It should be appreciated that this is just one example of connections within a multi-chip module including a plurality of dies (that may or may not be formed with different device technologies), as the invention is not limited in this respect.

FIG. 11 is a connection schematic 1100 for a multi-chip module 1110 comprising any one of the circuits illustrated in FIGS. 6-7, or any other circuit implementing VVA control methods. Multi-chip module 1110 includes a VVA die 1120 and a control die 1130, and may be similar to multi-chip module 1010, except that an input signal terminal on the control die may not be present, since control die 1130 does not utilize the input signal to regulate the control voltage applied to the VVA 1120. Otherwise, the connections and terminals of multi-chip module 1110 may be similar to those of multi-chip module 1010.

This invention is not limited in its application to the details of construction and the arrangement of components set forth in the description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method of controlling a signal applied to a control terminal of a variable voltage attenuator, the method comprising acts of:
(A) detecting an output signal of the variable voltage attenuator;
(B) generating a logarithm of the detected output signal of the variable voltage attenuator; and
(C) generating the signal applied to the control terminal of the variable voltage attenuator at least partially based on the logarithm of the detected output signal of the variable voltage attenuator.

2. The method of claim 1, wherein the act (C) further comprises generating the signal applied to the control terminal of the variable voltage attenuator at least partially based on a set signal.

3. The method of claim 2, further comprising an act, as a result of act (C), extending a linear-in-dB range of the output signal versus the set signal as compared to a linear-in-dB range of the variable voltage attenuator alone.

4. The method of claim 3, wherein a linear-in-dB error is less than about ±0.2 dB over a voltage range of the set signal of about greater than about 0.5 V.

5. The method of claim 2, wherein the set signal comprises an analog set signal.

6. The method of claim 5, further comprising an act of generating the analog set signal at least partially based on a digital set signal.

7. The method of claim 1, further comprising acts of:
detecting an input signal of the variable voltage attenuator; and
generating a logarithm of the detected input signal of the variable voltage attenuator.

8. The method of claim 7, wherein the act (C) further comprises an act of generating the signal applied to the control terminal of the variable voltage attenuator at least partially based on the logarithm of the detected input signal of the variable voltage attenuator.

9. The method of claim 8, wherein the act (C) further comprises an act of generating the signal applied to the control terminal of the variable voltage attenuator at least partially based on a set signal.

10. The method of claim 9, further comprising an act, as a result of act (C), extending a linear-in-dB range of the output signal versus the set signal as compared to a linear-in-dB range of the variable voltage attenuator alone.

11. The method of claim 10, wherein a linear-in-dB error is less than about ±0.2 dB over a voltage range of the set signal of grater than about 0.5 V.

12. A circuit including a variable voltage attenuator, the variable voltage attenuator comprising an input terminal, an output terminal, and a control terminal, the circuit comprising:
a first logarithmic signal detector having an input terminal coupled to the output terminal of the variable voltage attenuator; and
a summing element having a first input terminal coupled to an output terminal of the first logarithmic signal detector and an output terminal coupled to the control terminal of the variable voltage attenuator.

13. The circuit of claim 12, wherein a second input terminal of the summing element is configured to receive an analog set signal.

14. The circuit of claim 13, further comprising a digital-to-analog converter having an output terminal coupled to the second input terminal of the summing element and an input terminal configured to receive a digital set signal.

15. The circuit of claim 13, further comprising a second logarithmic signal detector having an input terminal coupled to the input terminal of the variable voltage attenuator and an output terminal coupled to a third input terminal of the summing element.

16. The circuit of claim 15, further comprising a digital-to-analog converter having an output terminal coupled to the second input terminal of the summing element and an input terminal configured to receive a digital set signal.

17. The circuit of claim 15, wherein the first and the second logarithmic signal detectors comprise power detectors.

18. A circuit including a variable voltage attenuator, the variable voltage attenuator comprising an input terminal, an output terminal, and a control terminal, the circuit comprising:
means for detecting an output signal of the variable voltage attenuator;
means for generating a logarithm of the detected output signal of the variable voltage attenuator; and
means for generating the signal applied to the control terminal of the variable voltage attenuator at least partially based on the logarithm of the detected output signal of the variable voltage attenuator.

19. The circuit of claim 18, further comprising means for generating the signal applied to the control terminal of the variable voltage attenuator at least partially based on a set signal.

20. The circuit of claim 18, wherein a linear-in-dB error is less than about ±0.2 dB over a voltage range of the set signal of about greater than about 0.5 V.

21. The circuit of claim 18, further comprising:
means of detecting an input signal of the variable voltage attenuator; and
means for generating a logarithm of the detected input signal of the variable voltage attenuator.

22. The circuit of claim 21, wherein the means for generating the signal applied to the control terminal of the variable voltage attenuator generates the signal applied to the control terminal of the variable voltage attenuator at least partially based on the logarithm of the detected output signal and the logarithm of the detected input signal of the variable voltage attenuator.

23. A circuit comprising:
a first input terminal configured to receive an input signal;
an output terminal configured to output an attenuated input signal; and
a second input terminal configured to receive a set voltage that at least partially determines the attenuation of the attenuated input signal,
the attenuated input signal having a power such that the power versus the set voltage is linear-in-dB for a range of the set voltage greater than 0.5 V.

24. The circuit of claim 23, wherein the power versus the set voltage is linear-in-dB for a range of the set voltage greater than 2.0 V.

25. The circuit of claim 23, wherein the circuit is formed on a plurality of chip dies.
